(19) United States
(12) Patent Application Publication
(10) Pub. No.: US 2006/0075959 A1
(43) Pub. Date: Apr. 13, 2006

(54) Trimethylgallium, a method for producing the same and a gallium nitride thin film grown from the trimethylgallium

(75) Inventors: Masanobu Matsubara, Niihama-shi (JP); Ken Shimada, Niihama-shi (JP); Naohiro Nishikawa, Tsukuba-shi (JP); Yoichi Kadota, Funabashi-shi (JP)

Correspondence Address: FOLEY AND LARDNER LLP;SUITE 500, 3000 K STREET NW, WASHINGTON, DC, 20007, US

(73) Assignee: SUMITOMO CHEMICAL COMPANY, LIMITED

(21) Appl. No.: 11/246,550

(22) Filed: Oct. 11, 2005

(30) Foreign Application Priority Data
Oct. 13, 2004 (JP) 2004-298564

(51) Int. Cl. C30B 23/00; C30B 25/00; C30B 28/12; C30B 28/14

(52) U.S. Cl. 117/89

(57) ABSTRACT

The present invention provides a trimethylgallium which has less than 0.1 ppm of a total organic silicon compound content; and a method for producing the trimethylgallium comprises hydrolyzing trimethylaluminum as a raw material, extracting organic silicon compound contained with a solvent, quantifying methyltriethylsilane by a Gas Chromatography-Mass Spectrometry, selecting a trimethylaluminum having less than 0.5 ppm of methyltriethylsilane content for the raw material, purifying by distillation, followed by reaction with gallium chloride and then distilling the reactant solution to obtain the trimethylgallium.

### FIELD OF THE INVENTION

The present invention relates to a trimethylgallium, a method for producing the same and a gallium nitride thin film grown from the trimethylgallium.

### BACKGROUND OF THE INVENTION

As nitride compound semiconductors having gallium nitride compound semiconductor layer, are known, for example, semiconductors having n-type and/or p-type layer, for example, represented by a formula InₓGa_{y}Al_{z}N (each of x, y and z is from 0 to 1, wherein x+y+z=1), as a layer of gallium nitride compounds grown on a sapphire substrate. The one having both of n-type and p-type layer is used as a material for a light emitting device such as a light emitting diode emitting ultra violet, blue or green colors, or laser diode emitting ultra violet, blue or green colors.

Such nitride compound semiconductors are produced in a multi-layer structure including a gallium nitride thin layer by a methods such as a molecular beam epitaxy method (hereinafter abbreviated as MBE), a metal organic vapor phase epitaxy (hereinafter abbreviated as MOVPE), a hydride vapor phase epitaxy method (hereinafter abbreviated as HVPE), and the like.

When producing light emitting diodes or laser diodes having high brightness, it is necessary that the carrier concentration in n-type and p-type layer is adjusted to high concentration and that the concentration is homogenous in the layers. While impurities are doped in order to adjust the carrier concentration, the carrier concentration is not necessarily dispersed uniformly in the layer.

It is well known that the quality of thin-film semiconductors deteriorated by the impurities, such as inorganic silicon contained in the organic metal compound used as a raw material. Therefore, the organic metal compounds having much higher purity are desired.

The known method for purifying the organic metal compound includes, for example, a method that the organic metal compound is purified by contacting with metallic sodium, metallic potassium and the like in a solvent. In this method, silicon content in the purified organic metal compound is determined by an atomic absorption spectrophotometer analysis, wherein the purified organic metal compound is subjected to hydrolysis, followed by dissolution in dilute hydrochloric acid. As a result, the trimethylgallium containing 0.1 ppm of inorganic silicon is obtained (see Example of U.S. Pat. No. 4,797,500).

Another known method includes a method that an organic metal compound in the liquid state is purified by being cooled down to partly crystalize and then eliminating liquid phase.

In this method, silicon content in the purified organic metal compound is determined by diluting the purified organic metal compound with a hydrocarbon, followed by hydrolysis, then analyzing the extracted organic silicon compound in the hydrocarbon solvent with a Inductively Coupled Plasma-Atomic Emission Spectrometry. As a result, the trimethylaluminum containing 0.8 ppm of organic silicon compound in terms of silicon atom (see Example of JP08-012678A).

Enhancement of semiconductor performance requires such organic gallium compounds that has higher purity than the conventional and provide an adjusted and stable carrier concentration in a film when a gallium nitride thin film is produced from the organic gallium compounds.

### SUMMARY OF THE INVENTION

The one of the objects of the invention is to provide a trimethylgallium of which purity is much higher than the conventional, especially a trimethylgallium which contains little organic silicon compounds and is stably controllable carrier concentration when forming a gallium nitride thin film (hereinafter being referred to as “GaN”). Another object of the invention is to provide a method for producing the trimethylgallium and a gallium nitride thin film grown from the trimethylgallium.

The inventors of the invention have diligently studied to stabilize carrier concentration, found the facts that organic silicon compound among the impurities affects stability of a carrier concentration, application of a trimethylgallium having less than 0.1 ppm of a total content of silicon compound allows the carrier concentration of non-doped GaN to be stably controlled being equal to or less than 1×10¹⁶ cm⁻³, therefore, the carrier concentration of both of n-type and p-type layers obtained by being doped with impurities can be stably adjusted in high level; and the trimethylgallium can be produced by quantifying methyltriethylsilane in trimethylaluminum as a raw material by a Gas Chromatography-Mass Spectrometry, selecting a trimethylaluminum having less than 0.5 ppm of methyltriethylsilane content for the raw material, purifying the selected trimethylaluminum by distillation, followed by reaction with gallium chloride to obtain a reactant and then distilling the reactant solution to obtain a trimethylgallium; and achieved the invention.

In the invention, the content of total organic silicon compounds is represented by a weight ratio of silicon atom of the total organic silicon compounds to metal atom of the organic metal compound to be measured. In the present invention, that the content of total organic silicon compounds in a trimethylgallium is less than 0.1 ppm means that the weight ratio of the silicon atom of the total organic silicon compounds to the gallium atom of the trimethylgallium is less than 0.1 ppm. This content is usually measured by ICP-AES: i.e. Inductively Coupled Plasma-Atomic Emission Spectrometry.

The content of individual organic silicon compounds such as methyltriethylsilane and the like is represented by a weight ratio of silicon atom of individual organic silicon compounds to the organic metal compound to be measured. In the present invention, that the content of methyltriethylsilane in a trimethylaluminum is less than 0.5 ppm means that the weight ratio of the silicon atom of the methyltriethylsilane to the trimethylaluminum is less than 0.5 ppm. This content is usually measured by GC-MS: i.e. Gas Chromatography-Mass Spectrometry.

In the present invention, a trimethylgallium has less than 0.1 ppm of a total organic silicon compound content.

Conducting the content of total organic silicon compounds in the trimethylgallium less than 0.1 ppm makes it possible to stably control the carrier concentration of non-doped GaN equal to or less than 1×10¹⁶ cm⁻³; consequently, to stably adjust in high level the carrier concentration of both of n-type and p-type layers obtained by impurity doping.

A method for producing a trimethylgallium having less than 0.1 ppm of a total organic silicon compound content comprises hydrolyzing trimethylaluminum as a raw material, extracting organic silicon compound contained in the hydrolysate with a solvent, quantifying methyltriethylsilane by a Gas Chromatography-Mass Spectrometry, selecting a trimethylaluminum having less than 0.5 ppm of methyltriethylsilane content for the raw material, purifying the selected trimethylaluminum by distillation, followed by reaction with gallium chloride to obtain a reactant and then distilling the reactant solution to obtain a trimethylgallium.

Even if organic silicon compounds other than methyltriethylsilane are present equal to or more than 1 ppm, it is possible to obtain a trimethylgallium having less than 0.1 ppm of a total organic silicon compound content; however, if not applying a trimethylaluminum having less than 0.5 ppm of methyltriethylsilane content, a trimethylgallium having less than 0.1 ppm of a total organic silicon compound content may not be obtained.

Another method comprises purifying a trimethylaluminum as a raw material by distillation before quantifying methyltriethylsilane contained in the trimethylaluminum of the raw material.

As well as the method mentioned before, a trimethylgallium having less than 0.1 ppm of a total organic silicon compound content can be obtained.

A gallium nitride thin film is grown from the trimethylgallium mentioned above or the trimethylgallium obtained by the production method mentioned above.

The carrier concentration of this gallium nitride thin film is stable.

### BRIEF DESCRIPTION OF THE DRAWING

FIG. 1 is a diagram illustrating a correlation between the carrier concentration and the consumption ratio based on the filled amount of an organic metal cylinder.

### DETAILED DESCRIPTION OF THE PREFERRED EMBODIMENT

The trimethylgallium (hereinafter being abbreviated as “TMG”) of the invention is characterized by that the content of total organic silicon compounds is less than 0.1 ppm; when the content of total organic silicon compounds is equal to or more than 0.1 ppm, it may not stably control the carrier concentration of non-doped GaN equal to or less than 1×10¹⁶ cm⁻³; consequently, difficult to stably adjust in high level the carrier concentration of both of n-type and p-type layers obtained by impurity doping. The content of total organic silicon compounds is preferably zero.

The method for producing the TMG of the invention is explained below.

The TMG is usually produced by purifying a trimethylaluminum (hereinafter being abbreviated as “TMA”) by distillation, followed by reaction with gallium chloride to obtain a reactant and then distilling the reactant.

In the TMA as a raw material, various kinds of impurities are contained due to production methods or source substances applied therefor. Of the impurities in the TMA as the raw material, from a few to several dozen ppm of organic silicon compounds are usually contained. The organic silicon compounds include tetramethylsilane (hereinafter being abbreviated as “TMS”), ethyltrimethylsilane (hereinafter being abbreviated as “ETMS”), methyltriethylsilane (hereinafter being abbreviated as “MTES”), tetraethylsilane (hereinafter being abbreviated as “TES”) and the like, the content thereof varies depending on the production method of TMA or the like.

Even if organic silicon compounds other than MTES are present being from a few to several dozen ppm in the raw TMA, it is possible to obtain a trimethylgallium having less than 0.1 ppm of a total organic silicon compound content by the method mentioned above; however, if the content of MTES contained in the raw material is not less than 0.5 ppm, it is impossible to obtain a trimethylgallium having less than 0.1 ppm of a total organic silicon compound content.

This reason is thought such that the organic silicon compounds involving ETMS other than MTES can be eliminated by distilling TMA as the raw material; however, MTES can not be eliminated by the distillation due to the boiling point of MTES being almost same to that of TMA (127° C.); and the MTES contaminating the purified TMA is transformed to ETMS in the course of TMG formation reaction; since the boiling point of ETMS (boiling point: 62° C.) is near to that of TMG (boiling point: 56° C.), this transformed ETMS is consequently hardly eliminated when purifying the TMG by distillation.

In the invention, according to MTES content of the raw TMA determined by analysis, the TMA having less than 0.5 ppm of MTES content, preferably less than 0.3 ppm, or more preferably less than 0.1 ppm is selected for application. Choice of the low content restricts possible sources for the raw TMA, however, this makes distillation conducted before and after the reaction easy.

The content of total organic silicon compounds in the TMA is usually analyzed, as mentioned above, after being subjected to pretreatment, by an Inductively Coupled Plasma-Atomic Emission Spectrometry (hereinafter occasionally being referred to as “ICP-AES”); this analysis method can determines the content of total silicon atom in total organic silicon compounds, however, the content of individual organic silicon compounds such as MTES and the like can not be determined.

In the invention, determination of the content of individual organic silicon compounds such as MTES is carried out, after being subjected to the pretreatment, by a Gas Chromatography-Mass Spectrometry (hereinafter occasionally being referred to as “GC-MS”).

The pretreatment is conducted by hydrolyzing TMA with acid, followed by extraction of organic silicon compounds with a solvent. The acid applied includes mineral acids such as hydrochloric acid, sulfuric acid and the like, they are usually applied as a solution of about 5 to 50% by weight. The solvent applied includes aromatic and aliphatic hydrocarbons such as toluene, xylene, hexane, heptane and the like. The hydrolysis is usually carried out for the TMA diluted with a solvent, and then the organic silicon compounds contained are extracted to the solvent. The organic silicon compounds extracted to the solvent are subjected to analysis of an ICP-AES and a GC-MS.

The pretreatment is specifically carried out as follows: preparing a cylinder loading the raw TMA, a vessel diluting the TMA, a vessel metering solvent and a equipment for stirring, connecting a vessel filled with acid solution for hydrolysis to a vessel filled with solvent to absorb generated gas, replacing the system with an inert gas such as argon and the like, cooling down the hydrolysis vessel and the generated-gas absorbing vessel to −20° C. and then pressing predetermined amount of TMA from the raw TMA loading cylinder into the TMA diluting vessel. Into the diluting vessel filled with TMA, predetermined amount of solvent is poured from the solvent metering vessel, followed by being sufficiently mixed. Thereafter, the TMA diluted with the solvent is dropped from the dilution vessel into the hydrolysis vessel filled with acid solution to hydrolyze the TMA. At this procedure, the temperature of the hydrolysis solution is maintained at about −5 to −20° C. by cooling along with adjusting the dropping amount of TMA. The gas generated by hydrolysis is absorbed in the absorption vessel filled with a solvent same to the dilution solvent. After completion of TMA dropping, the solution is stirred for a while (about 10 minutes) to complete the hydrolysis.

After finishing hydrolysis, the hydrolysis solution and absorption solution are mixed, and then the organic phase thereof is separated by a separatory funnel to subject the separated organic phase to analysis.

The organic phase is analyzed with a GC-MS according to an ordinary method to quantify each of organic silicon compounds.

To enhance analysis sensitivity, the organic phase is preferably concentrated. When analyzing high-boiling components such as MTES, TES and the like among the organic silicon compounds contained, hexane is applied as a solvent and about 10 to 90% of hexane in the organic phase is distilled off to subject the residual organic phase to analysis. Since, if the residue is highly concentrated or too much distilled off, the organic silicon compounds are accompanied to the fraction distilled off, the off-fraction is also subjected to the analysis.

When analyzing low-boiling components such as TMS, ETMS and the like, xylene is applied as a solvent and about 10 to 90% of xylene in the organic phase is distilled off to subject the fraction distilled off to analysis. Since, if distillation is insufficient, the organic silicon compounds are left in the residual fraction in distillation still, the residual fraction of the distillation still is subjected to the analysis. When analyzing low-boiling components such as TMS, ETMS and the like, analysis sensitivity may be enhanced by applying so called a headspace GC-MS, that is, a method of purging solvent to a gas phase, followed by the gas phase being subjected to GC-MS analysis.

After the total content of the organic silicon compounds, which is determined by the ICP-AES with respect to the organic silicon compounds extracted to the solvent by the pretreatment operation, is confirmed less than 0.5 ppm, or preferably less than 0.1 ppm, the TMA is allowed to apply for the raw TMA. That is, in this TMA, the content of the organic silicon compounds other than MTES is also less than 0.5 ppm, or preferably less than 0.1 ppm.

According to the result of the MTES content of a raw TMA analyzed by the procedures mentioned above, the TMA having less than 0.5 ppm of MTES content is selected.

Thereafter, the TMA having less than 0.5 ppm of MTES content is purified by distillation to eliminate low-boiling components and high-boiling components. The method of distillation is not particularly limited, after being subjected to an inert gas replacement, applying conventional reduced pressure distillation or ambient pressure distillation. Each of low-boiling components and high-boiling components is eliminated, depending on the operation conditions such as pressure and the like, in an amount of usually about 10 to 15% by weight and about 15 to 20% by weight respectively based on the TMA supplied. These low-boiling components and high-boiling components, if necessary, are purified by another purification method for reuse.

This distillation may be carried out before quantifying MTES content, when the MTES content is expected less than 0.5 ppm or the content of other impurities is high. However, in this distillation carried out in advance of quantifying, if resulting MTES content is found being equal to or more than 0.5 ppm according to the post-quantification, this advance distillation is possibly to be wasted; therefore, the usually preferable step is quantifying, selecting the TMA having less than 0.5 ppm of MTES content and then purifying by distillation.

Thereafter, the TMA which is purified by distillation to less than 0.5 ppm of MTES content is subjected to reaction with gallium chloride. Gallium chloride is usually put into a reactor and the reaction system is replaced with inert gas, followed by the gallium chloride (melting point: 78° C.) being heated to melt, and then the TMA is dropped in to react with the molten gallium chloride under stirring. The amount of the TMA to be added is usually almost same to that of the gallium chloride. The dropping rate of the TMA is adjusted not to raise the reaction temperature so much to maintain about 80 to 110° C.

After the addition being completed, the temperature is kept about 80 to 90° C. for about 4 to 8 hours to complete the reaction.

Thereafter, the reactant solution is distilled to obtain a TMG. The distillation method is not particularly limited, followed to the similar manner applied to TMA distillation. Each of the low-boiling components and high-boiling components is respectively eliminated in an amount of about 2 to 5% by weight and about 15 to 30% by weight based on the theoretical production amount of TMG to obtain about 65 to 80% by weight of a TMG product.

The total content of organic silicon compounds contained in thus obtained TMG is less than 0.1 ppm.

The analysis of the total organic silicon compounds contained in the TMG is carried out by the similar manner applied to the analysis of the total organic silicon compounds contained in the TMA. It is usually carried out by an ICP-AES.

Production of GaN thin film is carried out according to an ordinary method; for example, included are a metal organic vapor phase epitaxy (hereinafter abbreviated as “MOVPE”), a molecular beam epitaxy method (hereinafter abbreviated as “MBE”), a hydride vapor phase epitaxy method (hereinafter abbreviated as “HVPE”) and the like. As a specific example of a MOVPE method, the gas applied as an atmosphere gas during growth and a carrier gas of TMG may be such as nitrogen, hydrogen, argon, helium and the like by itself or the mixture thereof. Hydrogen gas or helium gas is more preferable due to suppressing pre-decomposition of a raw material under the atmosphere thereof. The temperature for crystal growth is equal to or more than 700° C. and equal to or less than 1100° C., to obtain GaN thin film having high crystallinity preferably equal to or more than 800° C., more preferably equal to or more than 900° C., or even more preferably equal to or more than 1000° C.

As a specific example of a MBE method, included is a gas source molecular beam epitaxy (hereinafter occasionally abbreviated as “GSMBE”) which supplies a nitrogen source such as nitrogen gas, ammonia and other nitrogen compounds in a gas state. In this method, nitrogen atom is often difficult to be taken into crystal due to the nitrogen source being chemically inactive. In such case, the efficiency of nitrogen intake may be improved by supplying the nitrogen source in activated state excited with microwave and the like.

When growing the GaN thin film by employing the MOVPE method, the TMG is applied with ammonia, hydrazine, methylhydrazine, 1,1-dimethylhydrazine, 1,2-dimethylhydrazine, t-butylamine, ethylenediamine by itself or a mixture thereof. Of these substances, since ammonia and hydrazine do not contain carbon atoms in their molecule, they are suitable for the thin film to avoid from carbon contamination.

As a substrate to grow the thin film, suitably applied are sapphire, SiC, Si, ZrB₂, CrB₂ and the like.

The GaN thin film grown by the method mentioned above, if being grown without impurity doping, represents n-type and equal to or less than 1×10¹⁶ cm⁻³ of carrier concentration. If being doped, to control conductive type and carrier concentration, being equal to or more than 5×10¹⁷ cm⁻³, preferably equal to or more than 1×10¹⁸ cm⁻³, or more preferably equal to or more than 2×10¹⁸ cm⁻³. The method of the invention can conduct the carrier concentration of the GaN thin film not doped with impurity (hereinafter being referred to as “non-doped”) to the n-type and equal to or less than 1×10¹⁶ cm⁻³; this allows, if being doped with n-type or p-type impurities, for any of cases to control a conductive type and a carrier concentration with favorable reproducibility

### EXAMPLES

The invention is explained by referring to Examples and Comparative Examples as follows, but should not be limited thereto.

(Analysis of Raw TMAs)

The raw TMA (1), TMA (2) and TMA (3), which were different in their supplier and grade, were analyzed about organic silicon compounds.

11.3 g of TMA (1) was diluted with 143.6 g of xylene and mixed. Into a hydrolysis vessel filled with 80 ml of acid solution which was 36% by weight of hydrochloric acid diluted in half, the TMA solution diluted with xylene was dropped to hydrolyze the TMA where the temperature of hydrolysis solution was maintained at about −5 to −20° C. by cooling as well as adjusting the dripping amount of the TMA. The gas generated by hydrolysis was absorbed with the absorption vessel filled with 30 ml of xylene. After dropping of TMA finished, the solution was stirred for about 10 minutes to complete hydrolysis.

After hydrolysis being completed, the hydrolysis solution and the absorption solution were mixed, followed by separation of xylene solution with a separatory funnel, and then the xylene solution was distilled to obtain 19.6 g of xylene solution.

This solution was analyzed with a headspace GC-MS (the trade name of equipment: HP7694, MS5973, manufactured by Agilent Technologies) to quantify TMS and ETMS. The results are shown in Table 1.

The hydrolysis was carried out in the similar manner except applying hexane in place of xylene, followed by separation of the hexane solution; the hexane solution was distilled to eliminate 34.9 g of hexane to obtain 109.5 g of a concentrated solution.

This concentrated solution was analyzed with a GC-MS (the trade name of equipment: MS Station JMS-700, manufactured by JEOL Ltd.) to quantify MTES and TES. The results are shown in Table 1.

The TMA (2) and TMA (3) were analyzed about organic silicon compounds according to the similar manner applied in the TMA (1). The results are shown in Table 1.

TABLE 1

| | TMA(1) | TMA(2) | TMA(3) |
|---|---|---|---|
| | Content | Content | Content |
| Organic silicon compound | (ppm) | (ppm) | (ppm) |
| TMS | 5 | 1.5 | — |
| ETMS | 1 | 0.1 | — |
| MTES | 16 | <0.1 | 0.3 |
| TES | 1 | <0.1 | <0.1 |
| Total | 23 | 2 | — |

(Production of TMG)

After the atmosphere of a distillation column of 108 mmf (inner diameter)×2150 mm (height) was replaced with nitrogen, 73 kg of TMA (1) was put into to purify the TMA by batch distillation method at 130° C. of a still temperature under an ambient pressure; resultant fractions obtained were 14% by weight of first fraction, 68% by weight of major drop and 18% by weight of still residue.

Thereafter, into 29 L of reactor equipped with stirrer, 10 kg of gallium chloride was put; after the atmosphere of the reactor was replaced with nitrogen gas, the gallium chloride was heated to melt, and then 12.6 kg of the major drop of TMA obtained above was dropped in to react with the molten gallium chloride under stirring. The dropping rate was adjusted to maintain the reaction temperature at about 90 to 105° C.

After completion of TMA addition, the reactant was kept at about 80° C. for about 6 hours to complete the reaction. Thereafter, 22.6 kg of the reactant was subjected to simple distillation to obtain 62% by weight of distillated fraction and 38% by weight of still residue.

Into a distillation column of 70 mmf (inner diameter)×1985 mm (height) of which atmosphere was replaced with nitrogen, 14 kg of the fraction obtained by this simple distillation was put, followed by batch distillation at 56° C. of column top temperature under an ambient pressure to obtain the TMG (1). In this distillation, resultant fractions obtained were 8% by weight of first fraction, 64% by weight of major fraction and 28% by weight of still residue.

The TMA (2) and TMA (3) were also subjected to production of TMG (2) and TMG (3) according to the similar manner applied to the TMA (1).

The TMG (1), TMG (2) and TMG (3) were analyzed about organic silicon compounds according to the similar manner applied to the TMA (1). The results are shown in Table 2.

The analysis results of the ICP-AES are also shown in the table 2. As well as the pretreatment for the GC-MS, TMG was diluted with xylene, followed by hydrolysis; then the xylene solution was analyzed about organic silicon compounds with a ICP-AES device SPS5000 (manufactured by Seiko Instruments Inc.).

TABLE 2

| | TMG(1) | TMG(2) | TMG(3) |
|---|---|---|---|
| | Content | Content | Content |
| Organic silicon compound | (ppm) | (ppm) | (ppm) |
| TMS | 0.05 | <0.01 | <0.01 |
| ETMS | 0.10 | <0.01 | <0.01 |
| MTES | <0.1 | <0.1 | <0.1 |
| TES | 0.2 | <0.1 | <0.1 |
| Sum of GC-MS | 0.3 | <0.1 | <0.1 |
| Sum of ICP-AES | 0.3 | <0.1 | <0.1 |

(Production of Gallium Nitride Thin Film)

Applying the TMG (2) of which content of the total organic silicon compounds was less than 0.1 ppm, a GaN layer was grown on a sapphire substrate with the MOVPE method as follows.

A sapphire having mirror-polished C-face was rinsed with organic solvent to be applied to a substrate. For crystal growth, a two-step growth process which applied GaN as a buffer layer grown at low temperature was employed. Under 1 atmospheric pressure at 485° C. of a susceptor temperature with applying hydrogen as a carrier gas, the carrier gas, TMG and ammonia were supplied to grow a GaN buffer layer of about 500 Å thickness. Thereafter, the temperature of the susceptor was raised up to 1040° C., followed by supplying the carrier gas, TMG and ammonia to grow a non-doped GaN layer of about 3 μm thickness.

The carrier concentration of these non-doped GaN layers which was determined from Capacitance-Voltage characteristics (hereinafter occasionally abbreviated as ‘C-V measurement’) of the depletion layer thereof was the measurable lower limit (1.0×10¹⁶ cm⁻³). The carrier concentration of the GaN layer, which was grown by applying the TMG without dependence on consumption ratio based on the filled amount of an organic metal cylinder, was able to be stably maintained in a low value below the measurable lower limit (1.0×10¹⁶ cm⁻³).

Applying the TMG (1) of which content of the total organic silicon compounds was 0.3 ppm, and the TMGs of 0.4 ppm and 0.5 ppm, a non-doped GaN layers were grown according to the similar procedure applied to TMG (2). The TMGs of which content of the total organic silicon compounds were respectively 0.4 ppm and 0.5 ppm were obtained by repeating production of TMG with applying the TMA (1) in which MTES was present; and the content of the total organic silicon compounds was analyzed with the ICP-AES.

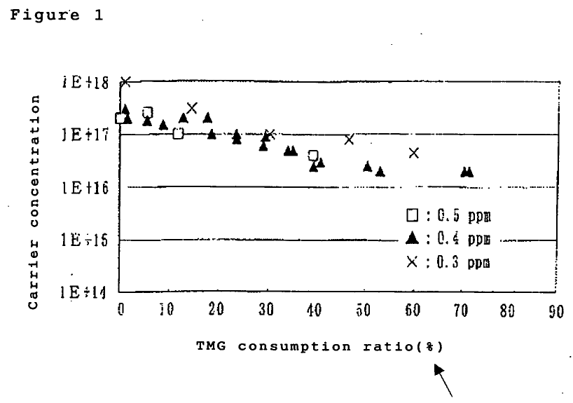

Of these non-doped GaN layers, the correlation between the carrier concentration determined from C-V measurement and the consumption ratio based on the filled amount of an organic metal cylinder is shown in FIG. 1.

According to the results of C-V measurement mentioned above, when the non-doped GaN layer was grown by applying TMG having equal to or more than 0.1 ppm of the total organic silicon compound content, the range of low consumption ratio based on the filled amount of an organic metal cylinder shows the carrier concentration being equal to or more than 1.0×10¹⁷ cm⁻³. Along with increase of consumption ratio of TMG (along with decrease of the amount left in the organic metal cylinder), the carrier concentration is lowered.

According to the invention, provided are the trimethylgallium of which purity is much higher than the conventional, especially the trimethylgallium which contains little organic silicon compounds and is stably controllable carrier concentration when forming a GaN thin film, a method for producing the trimethylgallium and the GaN thin film grown from the trimethylgallium.

1. A trimethylgallium having less than 0.1 ppm of a total organic silicon compound content.

2. A method for producing a trimethylgallium comprising hydrolyzing trimethylaluminum as a raw material, extracting organic silicon compounds contained in the hydrolysate with a solvent, quantifying methyltriethylsilane by a Gas Chromatography-Mass Spectrometry, selecting a trimethylaluminum having less than 0.5 ppm of methyltriethylsilane content for the raw material, purifying the selected trimethylaluminum by distillation, followed by reaction with gallium chloride to obtain a reactant and then distilling the reactant solution to obtain a trimethylgallium.

3. The method for producing a trimethylgallium according to claim 2, wherein the method comprises selecting a trimethylaluminum having less than 0.1 ppm of methyltriethylsilane content as a raw material.

4. The method for producing a trimethylgallium according to claim 2, wherein the method comprises purifying a trimethylaluminum as a raw material by distillation before quantifying methyltriethylsilane contained in the trimethylaluminum of the raw material.

5. A gallium nitride thin film grown from the trimethylgallium according to claim 1.

6. A gallium nitride thin film grown from the trimethylgallium obtained by the production method according to claim 2.
